(19) United States
(12) Patent Application Publication
(10) Pub. No.: US 2005/0174749 A1
(43) Pub. Date: Aug. 11, 2005

(54) Integrated filter construction

(75) Inventors: Matti Liikamaa, Vallingby (SE); Uno Henningsson, Haninge (SE); Karl-Gosta Forssen, Jarfalla (SE)

Correspondence Address: ERICSSON INC., 6300 LEGACY DRIVE, M/S EVR C11, PLANO, TX, 75024, US

(73) Assignee: Telefonaktiebolaget LM Ericsson (publ), Stockholm (SE)

(21) Appl. No.: 10/516,867

(22) PCT Filed: Jun. 28, 2002
(86) PCT No.: PCT/SE02/01305

(51) Int. Cl. H05K 7/14; H05K 7/18

(52) U.S. Cl. 361/799

(57) ABSTRACT

The present invention relates to an improved and compact filter arrangement and a method for a cost-efficient assembling of such an arrangement. The filter arrangement according to the present invention comprises a cover of the filter chassis that serves both as a mechanical and electrical shielding of the filter chassis and as a carrier of a printed circuit board for electrical components such that the filter chassis and the printed circuit board can refer to the same ground. It is possible to mount additional circuit boards, that are each shielded from each other, from the same direction on said first printed circuit board. The various units are automatically contacted during manufacturing by means of coupling components that connect adjacent units to each other.

### FIELD OF THE INVENTION

The present invention relates to an improved filter arrangement and a method for assembling of such an arrangement.

### BACKGROUND OF THE INVENTION

Filters are designed to be used for several kinds of signal processing, e.g. for signal adaptation or signal transforming in radio base stations for mobile telephony. It is possible to distinguish three main principals of filters: Waveguide filters, ceramic filters, and coaxial filters. The present invention focuses mainly on coaxial filters, or cavity filters, consisting of a plurality of cavities within which one or more centre conductors can be arranged. Each cavity with a centre conductor can be regarded as an oscillating circuit having an inductive and a capacitive component. The inductive component is mainly determined by the length of the centre conductor while the capacitive component depends on the diameter of said centre conductor and its distance from the side walls and the cover of the cavity. Oscillations in a cavity cause an electromagnetic field that induces a current in the neighbouring cavity so that an oscillation also arises in this cavity.

Such a filter is normally assembled of several separate units including, e.g., the electrical units for steering of the filter function, that are connected by appropriate cable connections. FIG. 1 shows an example of a filter arrangement according to the state of the art. In this example the filter unit 11, e.g. a cavity filter or waveguide filter, and units comprising the necessary electronics 12, 13 for operating the filter consist of separate units. The electrical contact between these units is done after the assembly by means of external cable connectors 14. However, when using such filters, e.g. in base stations for mobile telephony there are demands on a compact design and demands to be able to produce high numbers of such base stations in a rational and cost-efficient way.

### SUMMARY OF THE INVENTION

The present invention relates to an integrated filter arrangement.

It is a first object of the present invention to achieve a filter arrangement with a compact design.

It is another object of the present invention to achieve an easy and cost-efficient method for assembly of such a filter arrangement.

These and other objects are achieved by means of the filter arrangement according to the present invention comprising a cover of the filter chassis that serves both as a shielding for the waveguide within said chassis and as a carrier of a printed circuit board for electrical components such that the filter chassis and the printed circuit board can refer to the same ground. It is possible to mount additional circuit boards, that are each shielded from each other, from the same direction on said first printed circuit board. The various units are automatically contacted during manufacturing by means of coupling components that connect adjacent units to each other.

It is a first advantage of the present invention that the filter chassis and filter cover electrically refer to the same ground such that ground currents are avoided.

The filter arrangement according to the present invention can be manufactured in a rational and cost-efficient way. The electrical connecting of units that are part of said arrangement is done automatically during manufacturing by help of coupling components that are integrated parts of the filter chassis. Due to the fact that no cable connections between the filter units are necessary the number of components is reduced and the step of connecting the integrated units becomes unnecessary. In addition to this a more compact design for the filter arrangement can be achieved.

It is still another advantage of the filter arrangement according to the present invention to achieve an improved electrical contact between the units that are included in said arrangement.

The invention will now be described in more detail by help of preferred embodiments and with reference to the drawings.

### BRIEF DESCRIPTION OF THE DRAWINGS

FIG. 1 shows an example of a filter arrangement and its electrical contacting according to the state of the art.

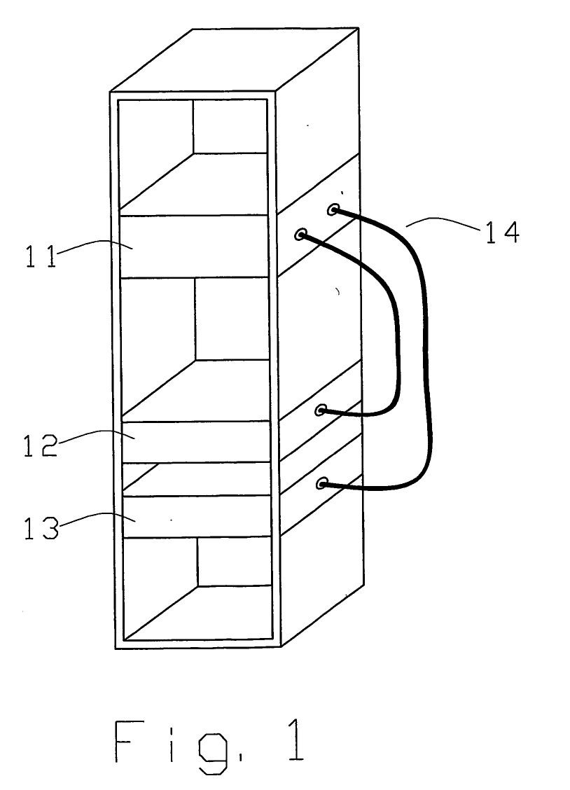

FIG. 2 shows a first embodiment of the filter arrangement according to the present invention.

FIG. 3 shows a cross section of a filter cover in a filter arrangement according to the present invention.

FIG. 4 shows a second embodiment of the filter arrangement according to the present invention.

### DETAILED DESCRIPTION

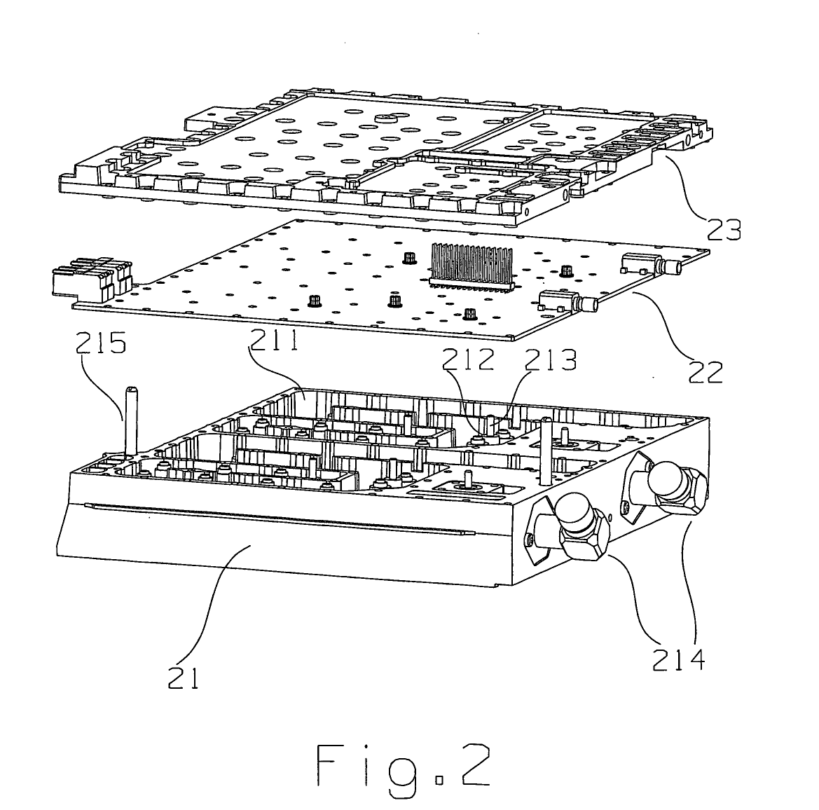

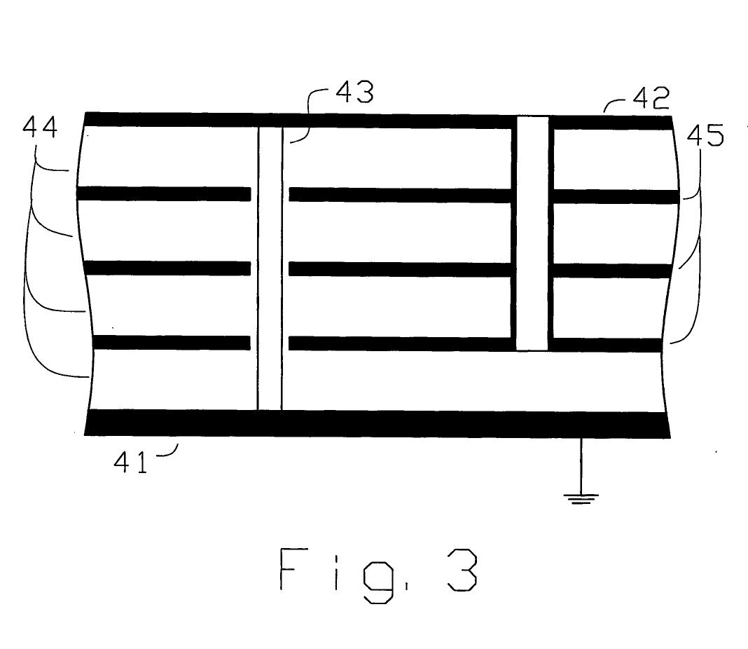

FIG. 2 shows a first embodiment of the filter arrangement according to the present invention. The arrangement consists of a filter chassis 21, which in this example is a cavity filter comprising a plurality of cavities 211 with centre conductors 212 that are arranged in said cavities. The external contacting of the filter is provided by connection components 214. A cover 22 is intended as mechanical protection and as electrical shielding of the filter cavities 211. It is the basic idea of the present invention to integrate the electronic equipment that is necessary for operating the filter within the filter construction. This is done by means of the arrangement of the present invention where the filter cover 22 has a function both for mechanical protection and electrical shielding as described above and, in addition to this, as a printed circuit board including at least a part of the electronic equipment that is necessary for operating the filter where the cover 22 constitutes thus a common ground level for the cavity filter and the printed circuit board. Both sides of the cover 22, i.e. the side that faces towards the filter cavities and the side on which the electrical components are mounted, are electrically connected with each other through said cover in order to achieve a filter arrangement where the filter chassis 21 and said printed circuit board can refer to a common ground level. The structure of the filter cover according to the present invention is shown in more detail in FIG. 3. The filter arrangement is preferably covered by a shielding cover 23 to provide a protection for the filter units and especially for the electrical components on the circuit board.

Instead of a time-consuming and costly contacting by means of cable contacts between circuit board and filter chassis the filter arrangement according to the present invention allows a rational contacting of parts that are included in the filter: In a preferred embodiment of the present invention this contacting is achieved by a galvanic coupling by help of appropriate coupling objects. In the embodiment shown in FIG. 2 said coupling objects consist of pegs 213 that can be manufactured in the same working process as the filter chassis and centre conductors, e.g. when casting the filter chassis, and are thus integrated in the chassis, e.g. on the bottom or on top of one of the centre conductors 212. In certain cases, e.g. in order to maintain a certain flexibility for contacting, it might be desirable to provide separate objects that are mounted afterwards at certain places in the filter chassis by means of an appropriate fastening method, e.g. screwing, pressing or a thermic contacting method. In order to achieve an electrical contact between filter chassis and printed circuit board each of the coupling objects is guided through a hollowness in the filter cover to selected contact areas on the filter cover 22 in its role as a circuit board. Alternatively, it would also be possible to mount these coupling objects on the side of the filter cover 22 that faces towards the filter chassis 21 such that said objects protrude in the cavities 211 of the filter chassis 21 after assembling.

The contacting by means of coupling objects as described above comprises the advantage that the entire outer electrical contacting to the filter can be done through the circuit board and said coupling objects without any cables. As another advantage, the contacting can be done in the same manufacturing step as the assembly of the filter, i.e. when mounting the filter cover on the filter chassis. Coupling objects that are mounted in the filter chassis can to a certain degree also facilitate a precise assembling of the units that are part of the filter arrangement.

A principally other way of contacting the filter chassis and the circuit board is to apply an inductive or capacitive coupling. For these alternatives, the coupling is mainly determined by geometrical dimensions, e.g. the distance and area in the space between cavity bottom and filter cover.

FIG. 3 shows in more detail the cover of a filter arrangement according to the present invention having a function as electrical shielding of the filter chassis and as carrier for electrical components. The figure shows a cross section of said cover comprising several layers of an electrically conductive material, e.g. copper. The lowest layer 41 that faces the filter chassis and the uppermost layer 42 on which the electrical components are arranged are electrically connected to each other by means of a hollowness 43 that is intended for interposing of a coupling object as described above. These layers constitute the common ground for both the filter chassis and the electrical components on the circuit board. The thickness of the layers is approximately 100 μm. In between said layers there are a number of conductor layers 45 that are connected to each other and to the uppermost layer 42 and used for connecting the various components on the circuit board of said uppermost layer. Each of these layers is shielded against other conductive layers and against the grounded layers 41, 42 by means of intermediate layers 44 of an electrically isolating material with low dielectric losses, e.g. based on teflon or ceramic.

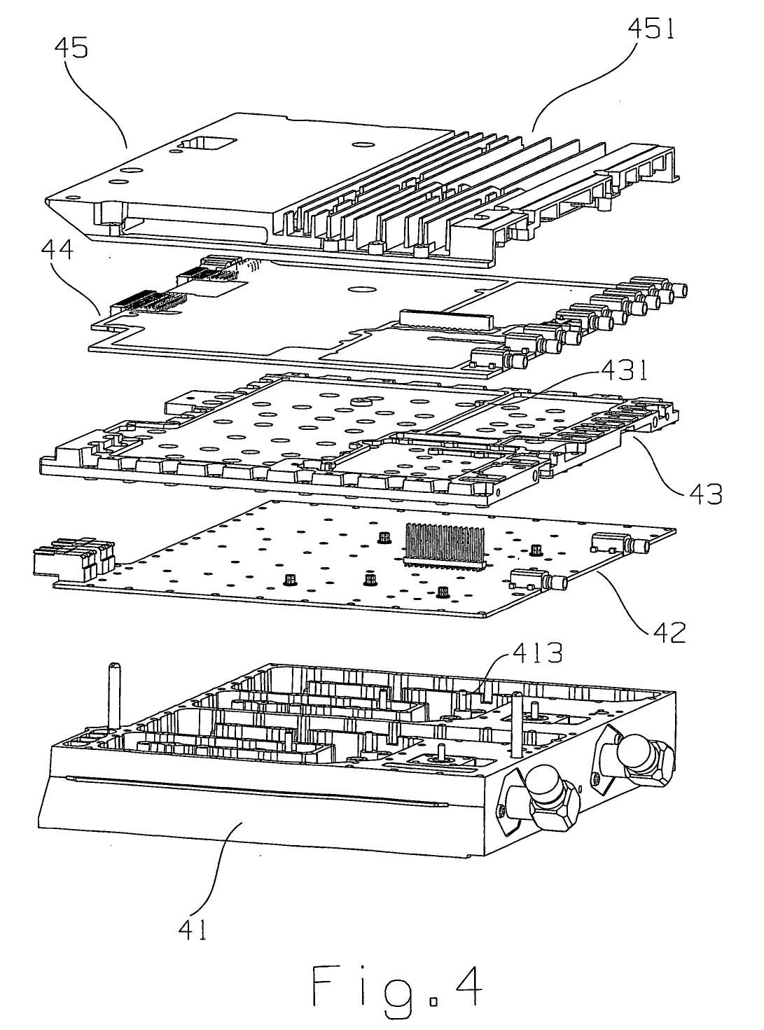

FIG. 4 shows a further development of the present invention where more than one printed circuit board is included in the filter arrangement. Also this embodiment is built on a filter chassis 41 as correspondingly described for FIG. 2. A filter cover 42 is mounted on said chassis and intended for mechanical protection and electrical shielding on the one hand and as a ground part for a printed circuit board on the other hand. In this embodiment, however, an additional circuit board 44 shall be included in the filter. This might be advantageous, e.g., for separating certain electric functions, e.g. regarding their function within the filter or with regard to possible mutual disturbances. A shielding cover 43 separates and shields the printed circuit boards from each other. Said cover 43 can be equipped with a framework on the upper and lower side consisting of bars 431 that can shield functions on one of the printed circuit boards from each other. The second printed circuit board 44 is covered by an outer shielding cover 45 to provide a protection for the filter units, especially for the electrical components on the circuit boards. If necessary, this shielding cover 45 can be designed with a ribbed surface 451 for cooling purposes.

The following describes a method for manufacturing a filter construction according to the above mentioned embodiments. Said method is characterised in that all units that are part of the filter construction, i.e. filter chassis 41, circuit boards 42, 44, and shielding elements 43, 45 are mounted on each other from one and the same side. The filter is assembled on a mechanical stable ground part, e.g. the filter chassis 41 as shown in FIG. 4. This ground part can be fixed in a certain position, e.g., within a manufacturing arrangement, and the other parts are mounted on it. The correct position of parts that are mounted on other already mounted parts can be adjusted, e.g., by means of a guiding peg 215 on which or possibly along which the parts can be guided to their correct positions. A precise assembling is also facilitated due to the coupling objects 413 that are integrated in the filter chassis 41 and guided through the circuit board when assembling the parts onto each other.

The invention is not restricted to the embodiments that have been described above and have been shown in the drawings but can be modified within the scope of the accompanying claims.

1-11. (canceled)

12. A filter arrangement, comprising:
a filter chassis including a filter cover for electrical and mechanical shielding of said filter, wherein the filter cover comprises a printed circuit board of electrically interconnected layers for applying an electrical pattern structure and for providing a common ground for said printed circuit board and said filter chassis; and
coupling means for simultaneous mounting and electrically interconnecting said filter chassis and one or more circuit boards.

13. The filter arrangement according to claim 12, wherein the coupling means are pegs.

14. The filter arrangement according to claim 13, wherein said pegs are separate objects that are mounted in the cavity bottom.

15. The filter arrangement according to claim 13, wherein the coupling objects are pegs that are mounted in the filter cover.

16. The filter arrangement according to claim .12, wherein the filter chassis and printed circuit boards are contacted by an inductive coupling.

17. The filter arrangement according to claim 12, wherein the filter chassis and printed circuit boards are contacted by a capacitive coupling.

18. The filter arrangement according to claim 12, wherein said circuit boards are shielded by help of a shielding cover.

19. The filter arrangement according to claim 12, wherein a shielding cover consists of a framework with crossbars for shielding of certain functions on one of the circuit boards.

20. The filter arrangement according to claim 19, wherein the circuit boards are arranged in such a way that the electrical components on each two boards are directed towards each other and wherein the intermediate shielding cover consists of two crossbar sections for shielding of functions on each of said two boards.

21. The filter arrangement according to claim 12, wherein an outer shielding cover provides an outer mechanical protection for the circuit boards.

22. A method for manufacturing a filter arrangement according to claim 12, wherein units that are included in said arrangement are mounted on each other from one and the same side.
